(19) United States
(12) Patent Application Publication
(10) Pub. No.: US 2025/0088192 A1
(43) Pub. Date: Mar. 13, 2025

(54) ULTRA-LOW POWER TEMPERATURE SENSOR DESIGN

(71) Applicant: Northeastern University, Boston, MA (US)

(72) Inventor: Aatmesh Shrivastava, Weston, MA (US)

(21) Appl. No.: 18/825,626

(22) Filed: Sep. 5, 2024

Related U.S. Application Data
(60) Provisional application No. 63/537,385, filed on Sep. 8, 2023.

(51) Int. Cl. H03L 1/02; G05F 3/30; H03M 1/46

(52) U.S. Cl. CPC H03L 1/023; G05F 3/30; H03M 1/46

(57) ABSTRACT

Methods, systems, and computer products are presented herein for determining temperature using ultra-low power temperature sensing systems. An ultra-low power (ULP) temperature sensing system comprises a proportional to absolute temperature (PTAT) current source, a switched-capacitor converter electrically coupled to the PTAT current source, and a ULP analog-to-digital converter (ADC) electrically coupled to the PTAT current source and the switched-capacitor converter. The PTAT current source is configured to generate a PTAT current that varies with an operating temperature. The switched-capacitor converter is configured to generate an analog voltage signal based on the PTAT current. The ULP ADC is configured to output a digital voltage value corresponding to the analog voltage signal.

### CROSS REFERENCE TO RELATED APPLICATIONS

This application claims the benefit of priority to U.S. Provisional Patent Application No. 63/537,385, filed Sep. 8, 2023; which is hereby incorporated by reference herein in its entirety.

### BACKGROUND

### Field of the Disclosed Subject Matter

The disclosed subject matter relates to ultra-low power temperature sensing systems for determining temperature. Particularly, the present disclosed subject matter is directed to temperature sensor circuits.

### Description of Related Art

Temperature sensor circuits are used in a wide range of applications across various industries. Their ability to measure and respond to temperature changes is critical for ensuring safety, efficiency, and performance of many systems. For example, temperature sensor circuits and timing circuits may be connected in various ways, primarily through the role that temperature plays in influencing the performance of a clock and its stability. The frequency of crystal oscillators (XO), commonly used for timing in electronic circuits, is sensitive to temperature changes. Temperature variations can cause the crystal's resonant frequency to drift, leading to errors in timing. Temperature sensors are used to monitor the temperature and provide compensation to the XO to maintain accurate clock frequencies. In systems requiring precise timing, such as telecommunications systems or GPS systems, temperature sensors help maintain clock accuracy by compensating for temperature-induced variations.

Temperature sensor circuits face several challenges, including having process variation, high power consumption, having an accurate proportional-to-absolute-temperature current, and the need for high precision. Therefore, there is a need for an ultra-low power (ULP) temperature sensing system that addresses challenges.

### SUMMARY OF THE DISCLOSED SUBJECT MATTER

The purpose and advantages of the disclosed subject matter will be set forth in and apparent from the description that follows, as well as will be learned by practice of the disclosed subject matter. Additional advantages of the disclosed subject matter will be realized and attained by the methods and systems particularly pointed out in the written description and claims hereof, as well as from the appended drawings.

To achieve these and other advantages in accordance with the purpose of the disclosed subject matter, as embodied and broadly described, the disclosed subject matter includes ultra-low power temperature sensing systems for determining temperature comprising a proportional to absolute temperature (PTAT) current source, a switched-capacitor converter electrically coupled to the PTAT current source, and a ULP analog-to-digital converter (ADC) electrically coupled to the PTAT current source and the switched-capacitor converter. The PTAT current source is configured to generate a PTAT current that varies with an operating temperature. The switched-capacitor converter is configured to generate an analog voltage signal based on the PTAT current. The ULP ADC is configured to output a digital voltage value corresponding to the analog voltage signal.

The analog voltage signal may be proportional to the operating temperature. The PTAT current source may be biased sub-threshold. The PTAT current source may comprise a constant transconductance. The PTAT current source may comprise at least one metal-oxide-semiconductor field-effect transistor (MOSFET) transistor electrically coupled to a plurality of bipolar junction transistors (BJTs). The at least one MOSFET transistor may comprise an NMOS transistor. The plurality of BJTs may comprise a plurality of PNP transistors. The switched-capacitor converter may comprise at least one switched-capacitor based resistance. The analog voltage signal may be generated by the PTAT current flowing through the switched-capacitor based resistance. The at least one switched-capacitor based resistance may comprise a plurality of switched capacitors, wherein a switching frequency of the plurality of switched capacitors is a clock frequency of a crystal oscillator (XO). The ULP ADC may comprise a Successive

Approximation Register (SAR) ULP ADC. The ULP ADC may comprise a comparator, sample and hold circuit, and a digital-to-analog converter (DAC). An output of the sample and hold circuit and an output of the DAC may be electrically coupled to inputs of the comparator. The sample and hold circuit may be configured to receive the analog voltage signal as input. The ULP ADC may further comprise Successive Approximation Register (SAR) logic coupled to an output of the comparator and to inputs of the DAC. The SAR logic may be configured to output the digital voltage value.

The disclosed subject matter also includes a method for temperature sensing. A PTAT current that varies with an operating temperature is generated by a proportional to absolute temperature (PTAT) current source. An analog voltage signal based on the PTAT current is generated by a switched-capacitor converter electrically coupled to the PTAT current source. A digital voltage value corresponding to the analog voltage signal is provided by a ULP analog-to-digital converter (ADC) electrically coupled to the PTAT current source.

The analog voltage signal may be proportional to the operating temperature. The PTAT current source may be biased sub-threshold. The PTAT current source may comprise a constant transconductance. The PTAT current source may comprise at least one metal-oxide-semiconductor field-effect transistor (MOSFET) transistor electrically coupled to a plurality of bipolar junction transistors (BJTs). The at least one MOSFET transistor may comprise an NMOS transistor. The plurality of BJTs may comprise a plurality of PNP transistors. The switched-capacitor converter may comprise at least one switched-capacitor based resistance. The method may further comprise generating, by the PTAT current flowing through the switched-capacitor based resistance, an analog voltage signal. The at least one switched-capacitor based resistance may comprise a plurality of switched capacitors. A switching frequency of the plurality of switched capacitors may be a clock frequency of a crystal oscillator (XO). The ULP ADC may comprise a Successive Approximation Register (SAR) ULP ADC. The ULP ADC may comprises a comparator, sample and hold circuit, and a digital-to-analog converter (DAC). An output of the sample and hold circuit and an output of the DAC may be electrically coupled to inputs of the comparator. The method may further comprise receiving, by the sample and hold circuit, the analog voltage signal. The ULP ADC may further comprise Successive Approximation Register (SAR) logic coupled to an output of the comparator and to inputs of the DAC. The method may further comprise outputting, by the SAR logic, the digital voltage value.

It is to be understood that both the foregoing general description and the following detailed description are exemplary and are intended to provide further explanation of the disclosed subject matter claimed.

The accompanying drawings, which are incorporated in and constitute part of this specification, are included to illustrate and provide a further understanding of the method and system of the disclosed subject matter. Together with the description, the drawings explain the principles of the disclosed subject matter.

### BRIEF DESCRIPTION OF THE DRAWINGS

A detailed description of various aspects, features, and embodiments of the subject matter described herein is provided with reference to the accompanying drawings, which are briefly described below. The drawings are illustrative and are not necessarily drawn to scale, with some components and features being exaggerated for clarity. The drawings illustrate various aspects and features of the present subject matter and may illustrate one or more embodiment(s) or example(s) of the present subject matter in whole or in part.

FIGS. 1A and 1B depict a first portion of an ultra-low power (ULP) temperature sensing system according to various embodiments of the present disclosure.

FIG. 2 depicts a block diagram of a second portion of a ULP temperature sensing system that includes an ULP 8-bit SAR Analog-to-Digital Converter (ADC) for converting an analog voltage signal, such as one generated from the analog circuit shown in FIGS. 1A and 1B, to a digital voltage value according to various embodiments of the present disclosure.

FIGS. 3A and 3B show histograms of the process variation of the thermal voltage measured by the ULP temperature sensing system, across 100 sample measurements according to various embodiments of the present disclosure.

FIG. 4 shows the measured frequency variation as a function of time for five different voltages in a ULP Timing Circuit system that includes the ULP temperature sensing system having 1 ppm/50 mV variation according to various embodiments of the present disclosure.

FIG. 5A depicts an 8-bit Digital-to-Analog Converter (DAC) in which digital bit values corresponding to a voltage are an input of the DAC and an output of the DAC is an analog voltage value according to various embodiments of the present disclosure. FIG. 5B shows a graph of a simulation of the 8-bit DAC of FIG. 5A when digital values were swiped at the DAC input over a series of 8-bit binary values, each 8-bit binary value corresponding to analog voltages from 0 to 1.2V at the output of the DAC according to various embodiments of the present disclosure.

FIGS. 6A and 6B show graphs of a simulation of a designed 8-bit SAR ADC according to various embodiments of the present disclosure.

FIG. 7A shows a block diagram of a portion of the 8-bit SAR ADC of FIG. 2 where a portion of the ADC is coupled to an 8-bit DAC according to various embodiments of the present disclosure. FIG. 7B shows a graph of the input voltage of the ADC portion of FIG. 7A and output voltage of the DAC of FIG. 7A as a function of time according to various embodiments of the present disclosure.

FIG. 8 shows a chip comprising the ultra-low power (ULP) temperature sensing system according to various embodiments of the present disclosure.

FIG. 9 is a flow chart depicting a method for temperature sensing according to various embodiments of the present disclosure according to various embodiments of the present disclosure.

### DETAILED DESCRIPTION

Reference will now be made in detail to exemplary embodiments of the disclosed subject matter, an example of which is illustrated in the accompanying drawings. The method and corresponding steps of the disclosed subject matter will be described in conjunction with the detailed description of the system.

For purpose of explanation and illustration, and not limitation, exemplary embodiments of the system in accordance with the disclosed subject matter are shown in the Figures presented herein. Similar reference numerals (differentiated by the leading numeral) may be provided among the various views and Figures presented herein to denote functionally corresponding, but not necessarily identical structures.

There are various advantages of the disclosed subject matter. As examples, the disclosed subject matter may be able to provide temperature sensing with an ultra-low power consumption, a high degree of stability, and a high degree of temperature sensing accuracy.

The ultra-low power temperature sensor may be used for various applications such as allowing for frequency compensation, to adjust for temperature drift, for a crystal oscillator (XO) used in timing circuits or other temperature sensing applications.

Various embodiments disclosed herein relate to an ultra-low power temperature sensing system for determining an operating temperature. The temperature sensing system, which may be referred to as a proportional to absolute (PTAT) circuit, may be based on a sub-threshold based switched capacitor PTAT current source for a high precision gm circuit. To eliminate the process variation, the resistor for the PTAT circuit may be implemented using switched capacitors, where the switching frequency of the switched capacitors may be the clock frequency of a XO. Such circuitry may provide a high precision resistor and an accurate PTAT current reference for high accuracy temperature sensing.

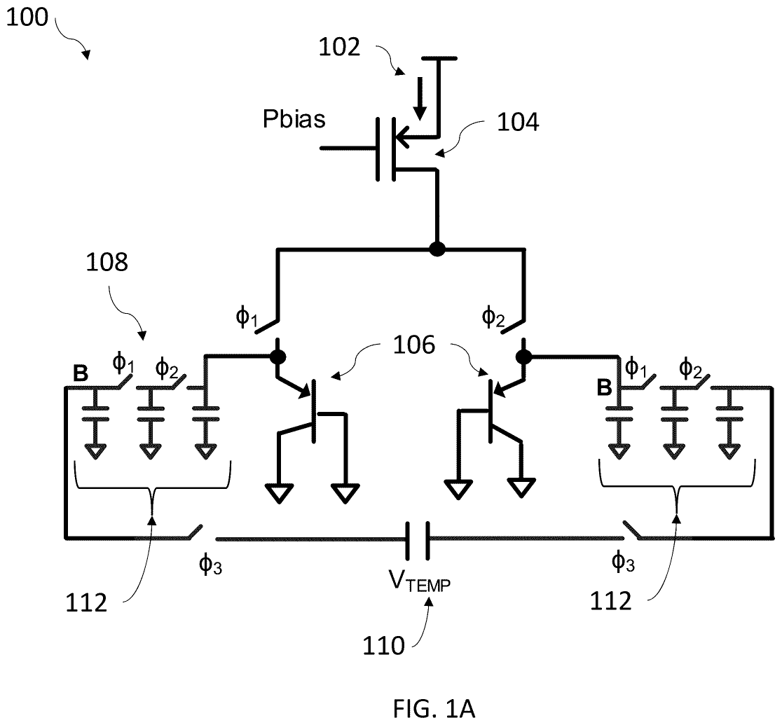

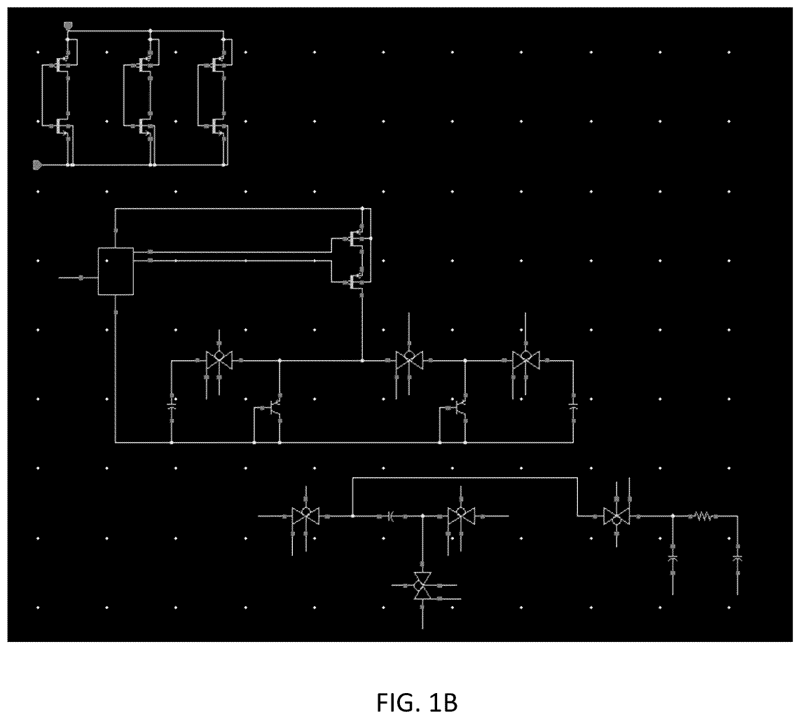

FIGS. 1A and 1B depict a first portion 100 of an ultra-low power (ULP) temperature sensing system. In particular, in accordance with various embodiments, FIGS. 1A and 1B illustrate the architecture of a portion of a temperature sensing analog circuit that uses a proportional to absolute temperature (PTAT) current source to generate a PTAT current 102, which may be used to generate an analog voltage signal, V_{TEMP} 110. The analog voltage signal may be proportional to an operating temperature of the circuitry in which the ULP temperature sensing system is deployed.

A PTAT current is a type of electrical current whose magnitude increases proportionally with absolute temperature. Achieving a PTAT current involves using specific circuit designs that can take advantage of the temperature-dependent characteristics of semiconductor devices. A PTAT current may be generated in several ways. The difference in base-emitter voltages of transistors with different current densities may be used to generate a PTAT current. As shown in FIG. 1A, a PTAT current source may be configured to generate a PTAT current 102 that varies with a temperature.

The PTAT current source may comprise one or more metal-oxide-semiconductor field-effect transistor (MOSFET) transistor 104 electrically connected in series with Bipolar Junction Transistors (BJTs) 106, as shown.

As temperature changes, the gate threshold voltage of the MOSFET transistor, which may be defined as the minimum voltage required to turn on the MOSFET transistor, may also change. This variation in threshold voltage may affect the current flowing through the MOSFET transistor, as the channel conductivity of the MOSFET is influenced by the temperature-induced changes in threshold voltage. This effect can be exploited to generate, such as by a PTAT current source, a current that is proportional to absolute temperature. The MOSFET transistor 104 may be an n-type metal-oxide-semiconductor (NMOS) transistor, which may use n-type (negatively doped) semiconductors as a source and a drain. Such n-type material may have a higher electron density compared to a p-type material used in p-type metal-oxide-semiconductor transistors.

The MOSFET 104 may be electrically connected in series to multiple Bipolar Junction Transistors (BJTs) 106 within the PTAT current source, as shown. The BJTs 106 may include a plurality of PNP transistors, which include two p-type layers separated by an n-type layer. A relatively small current applied to the base terminal of each BJT may control a relatively larger current flowing between the collector and emitter terminals, which may enable the BJT to amplify or switch electronic signals. In various embodiments, the temperature dependence of the base-emitter voltage and the voltage difference between the base and emitter terminals may be used to generate a PTAT current by the PTAT current source.

The PTAT current source may be biased in the subthreshold region to generate a PTAT current proportional to a temperature. The PTAT current source may have a constant transconductance over a range of conditions (e.g., a wide temperature range).

A switched-capacitor converter 108 may be electrically coupled to the PTAT current source. The switched-capacitor converter 108 may be configured to generate an analog voltage signal 110 based on the PTAT current. The switched-capacitor converter 108 may include at least one switched-capacitor based resistance which may include a plurality of switched-capacitors 112. The multiple switched capacitors 112 may be connected to each other, as shown, and electrically coupled to the PTAT current source. A switched capacitor may be an electronic circuit that performs functions by alternately transferring charges into and out of capacitors as electronic switches are toggled on and off. The switches used in switched-capacitor circuits may use MOSFETs or other types of transistors that are controlled by a switching frequency. The switching frequency of each the switched capacitors 112 may be a clock frequency of a XO. The analog voltage signal 110 may be generated by the PTAT current flowing through the switched-capacitor converter 108, which may equivalently operate as a switched-capacitor based resistance.

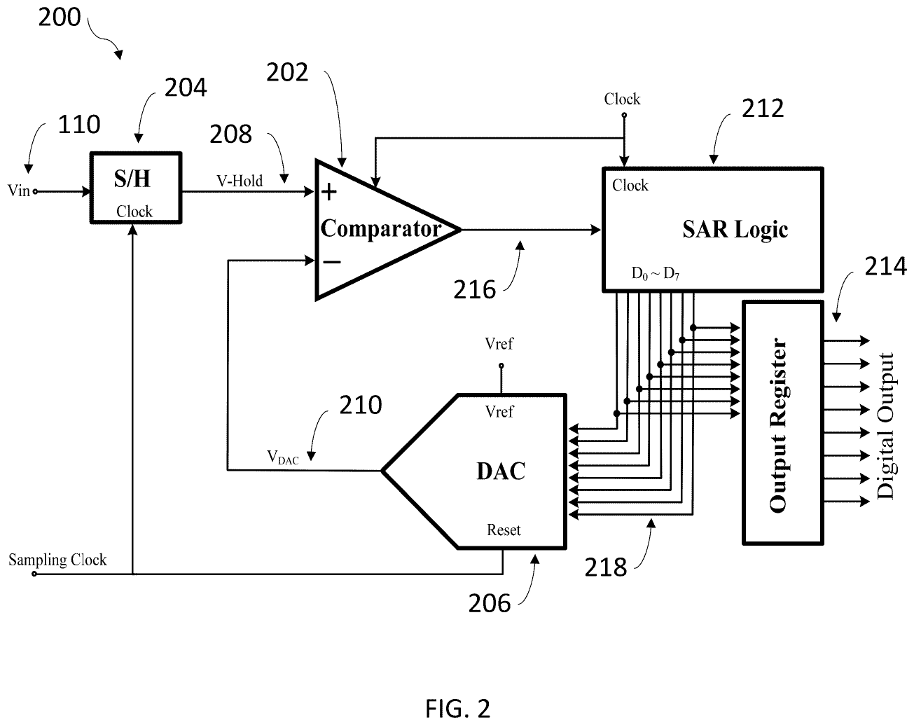

FIG. 2 depicts a block diagram of a second portion 200 of an ULP temperature sensing system that includes ULP 8-bit SAR Analog-to-Digital Converter (ADC) for converting an analog signal, such as analog voltage signal 110 generated from the analog circuit shown in FIGS. 1A and 1B, to a digital voltage value. The ULP ADC, shown as a part of portion 200, may be electrically coupled to the PTAT current source and the switched-capacitor converter 108, described above with reference to FIGS. 1A and 1B. The ULP ADC may be configured to output a digital voltage value corresponding to the analog voltage signal at its input, such as analog voltage signal 110. The ULP ADC may be a Successive Approximation Register (SAR) ULP ADC. A SAR ULP ADC is a type of ADC that uses a binary search technique to convert an analog signal into a digital representation. As shown in FIG. 2, the ULP ADC may include a comparator 202, sample and hold circuit 204, and DAC 206. The sample and hold circuit 204 may be clocked by an input clock as shown, and may be configured to receive an analog voltage signal, such as the analog voltage signal 110, as an input voltage. The sample and hold circuit output 208 and DAC output 210 may be electrically connected to the inputs of comparator 202. The ULP ADC may further include SAR logic 212, which may be clocked by an input clock as shown, and be configured to output a digital voltage value to an output register 214, which may store the output digital voltage value. The SAR logic 212 may be coupled to a comparator output 216 and to DAC inputs 218. The comparator 202 may be clocked by an input clock as shown, and may compare the ADC input voltage, such as analog voltage signal 110, to the output of DAC 206 and outputs the result to the SAR logic 212. This output of comparator 202 may indicate whether there is a difference between the values input to comparator 202, such as by indicating a logical high value if there is a difference between the input values and a logical low value if there is no difference between the input values. The SAR logic 212 may output an approximate binary code value corresponding to the voltage input to the DAC. The SAR logic 212 may receive an indication that its binary code may have to change when the output of comparator 202 indicates that there is a difference in the input voltages to the comparator. The SAR ULP ADC may perform an iterative conversion of its input voltage, such as analog voltage signal 110, by successively approximating its input voltage to determine a digital 8-bit binary value representation of its input voltage. For example, it may start with the Most Significant Bit (MSB) and work through the bits to the Last Significant Bit (LSB), using a comparator, such as comparator 202, to refine the approximation with each step. Such an iterative process may involve the SAR ULP ADC sampling its input voltage, such as analog voltage signal 110, comparing it with the DAC output 210, and updating its digital value output based on the comparison until a final 8-bit binary representation of its input voltage is obtained and output.

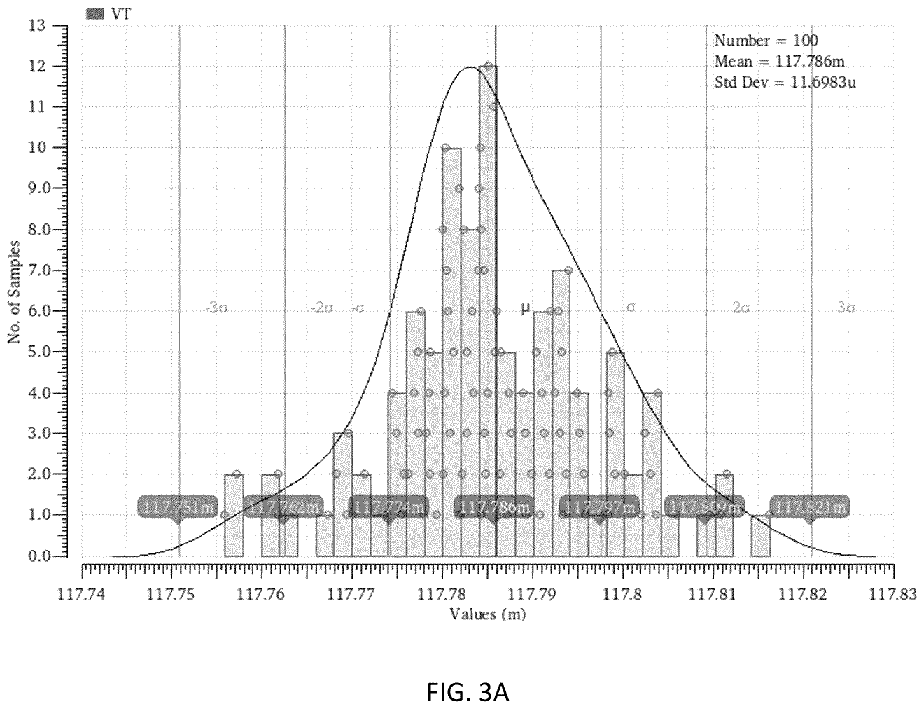

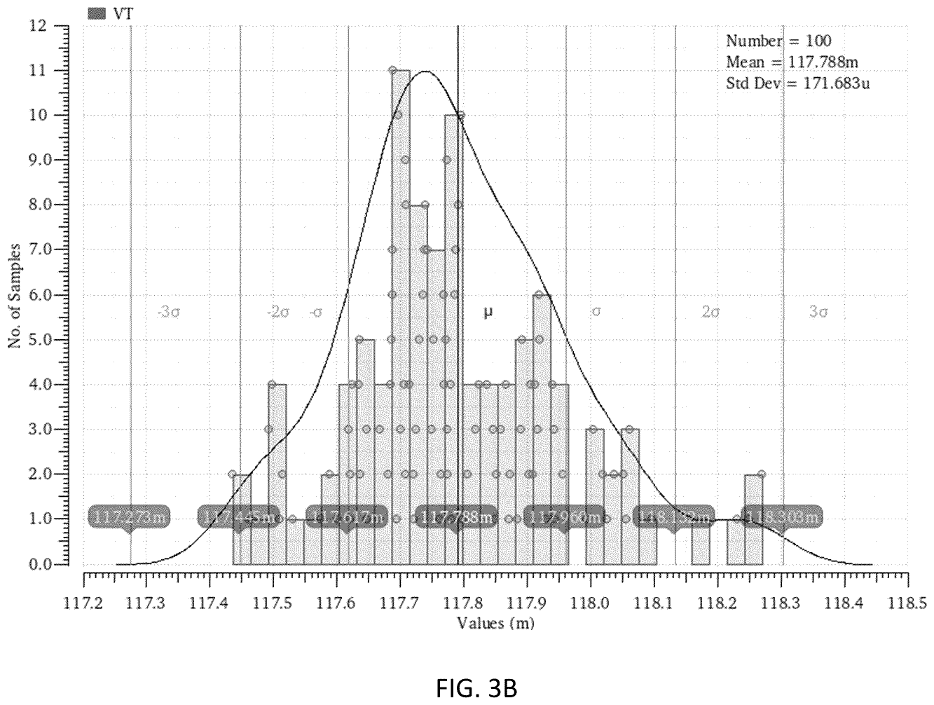

FIGS. 3A and 3B show histograms of the process variation of the thermal voltage measured by the ULP temperature sensing system, described herein, across 100 sample measurements. As shown in FIG. 3A, the average and standard deviation across 100 samples was 117.786 m and 11.6983 u, respectively. In FIG. 3B, the average and standard deviation across 100 samples was 117.788 m and 171.683 u, respectively. The measurements exhibited a generally normal distribution with low variance, as indicated by the small standard deviation.

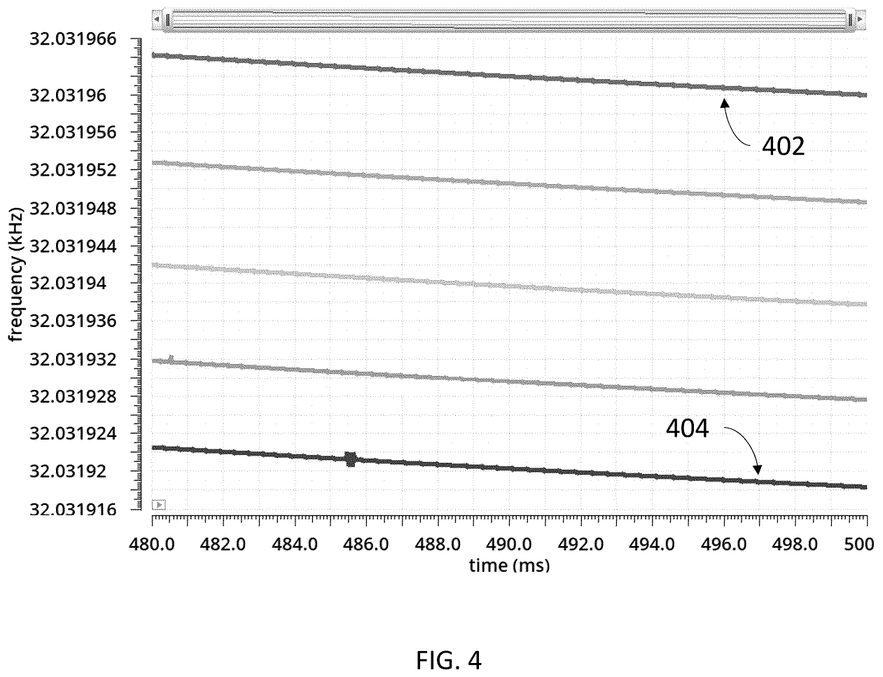

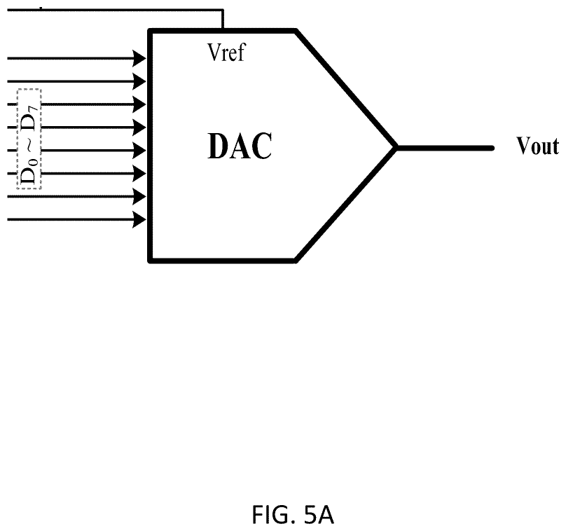

FIG. 4 shows the measured frequency variation as a function of time for five different voltages in a ULP Timing Circuit system that includes the ULP temperature sensing system, as described herein, having 1 ppm/50 mV variation. Specifically, to show the range of voltages, the voltages denoted as 402 and 404 are −100 mV and 100 mV, respectively. The frequency variation measurement indicates how the frequency of the ULP Timing Circuit system changes over time when subjected to different voltage levels. The ULP Timing Circuit system had a frequency variation of 1 part per million per a 50 millivolt change in voltage. This provides a measure of the sensitivity of the timing circuit to voltage changes, highlighting its precision and stability, which may be an indication of the advantages of the ULP temperature sensing system. Overall, each of the reference voltages measurements showed a near-linear relationship between frequency and time which demonstrated that the frequency of the signal generated by the system changed at a constant rate.

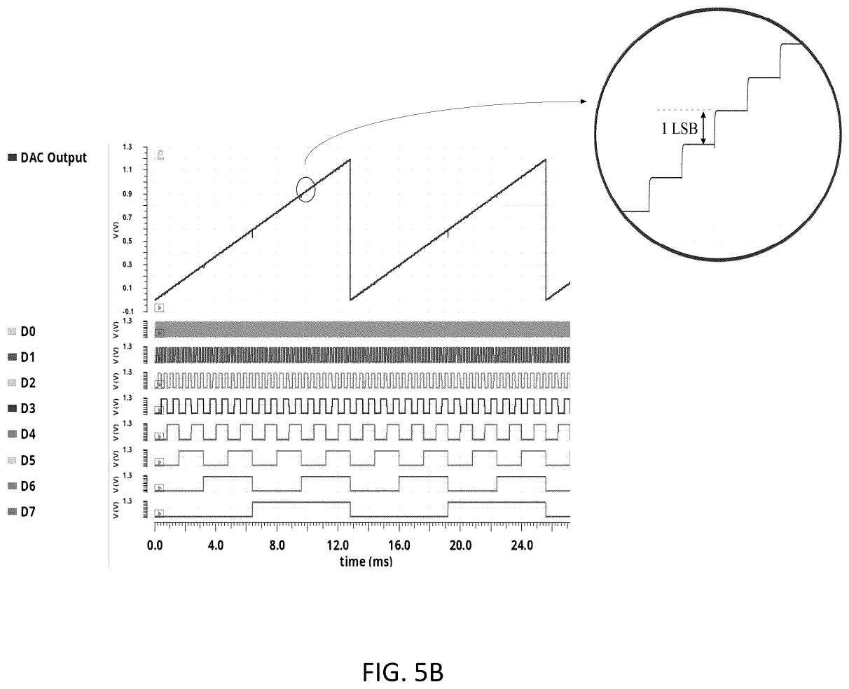

FIG. 5A depicts an 8-bit DAC in which digital bit values corresponding to a voltage are an input of the DAC and an output of the DAC is an analog voltage value. FIG. 5B shows a graph of a simulation of the 8-bit DAC of FIG. 5A when digital values were swiped at the DAC input from 00000000 to 11111111, each 8-bit binary value corresponding to analog voltages from 0 to 1.2V at the output of the DAC. The graph shows the DAC output voltage as a function of time and the inputs of the DAC. The inputs of the DAC were a series of discrete digital 8-bit binary values (D0-D7 in the FIG. 5B). Each value corresponded to a specific point in time. The DAC translated these digital values into an analog voltage. The output was updated at discrete intervals based on the digital values input to the DAC. Because the DAC updated its output in discrete steps according to digital input values, the resulting analog output waveform appeared as a series of steps referred to as a staircase waveform as shown in FIG. 5B.

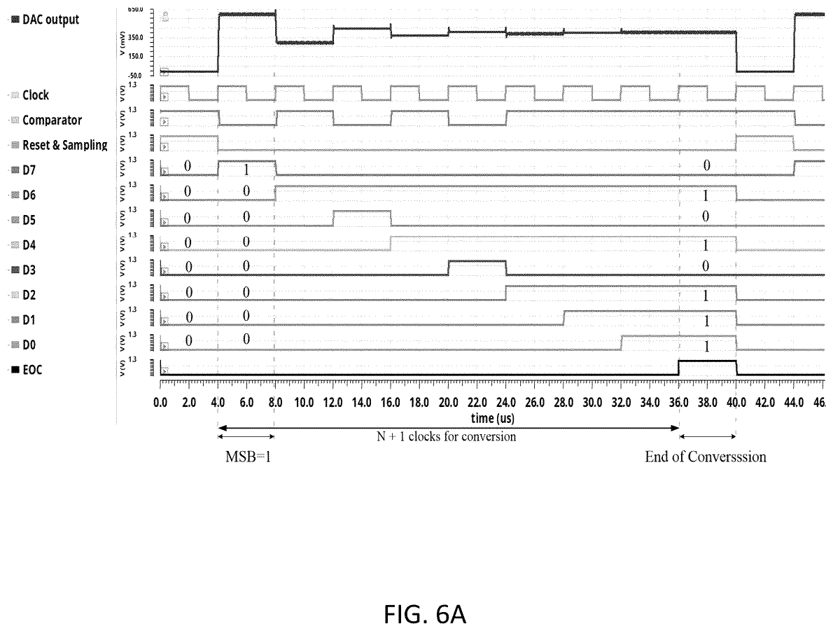

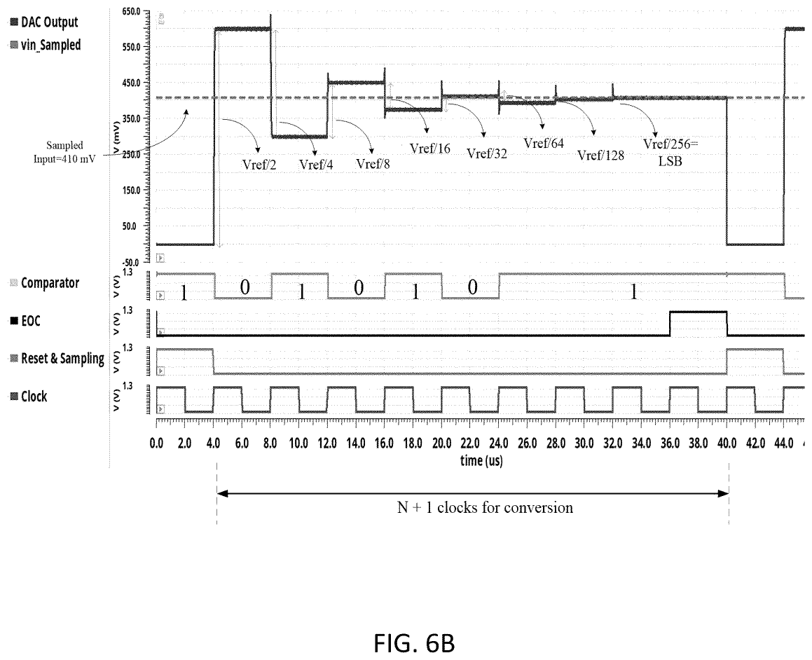

FIGS. 6A and 6B show graphs of a simulation of a designed 8-bit SAR ADC. The SAR operation may be based on a binary search algorithm. In the simulation results, the DAC output displayed a staircase waveform that changed as the SAR algorithm adjusted the DAC's value during its binary search. The clock signal, which was a standard period square wave, marked the time for each phase of the conversion process. The comparator output toggled between logical high and low states based on whether the DAC output was higher or lower than the sampled analog input, guiding the SAR algorithm. The Reset and Sampling signal showed a signal that was either in a constant logical high or low state, through the observation period, to mark an initialization phase and to represent a period when the analog input is sampled and held constant. Digital values (D0-D7) showed the 8-bit digital output, with each bit switching between a logical high (1) and low (0) values to represent the final conversion result. Finally, The End of Conversion (EOC) signal transitioned to a logical high state at the end of a conversion cycle, signaling that the digital 8-bit binary output was complete.

As an example, the SAR logic may take N+1 cycles to convert an analog input to a digital output. In the first cycle, all the registers may be set to 0. Then in cycle 1, the Most Significant Bit (MSB) D7 may be set to 1. This may result in binary value of ‘10000000.’ This value may be converted to an analog output using the DAC and compared to the sample and hold circuit output. If the result of the DAC subtracted from the sample and hold circuit output is less than 0, then the MSB may be set to 0. In cycle 2, the next MSB, D6, may be acted on in the same manner. This cycle may continue until all bits are converted. Achieving the final value may be achieved through binary search. This search may be upward toward the reference voltage or downward toward zero voltage depending on the output of the comparator. When the final value is achieved, the control signal End of Conversion (EOC) may transfer the final value to the output register.

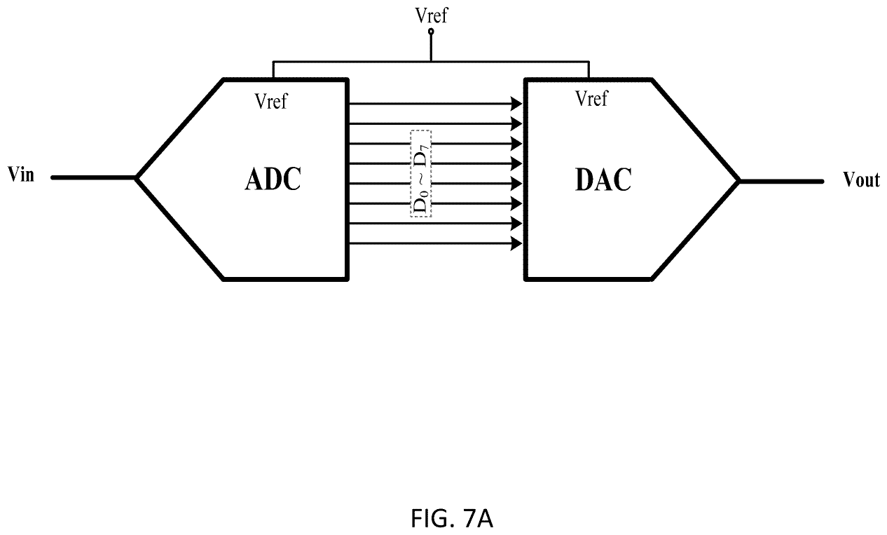

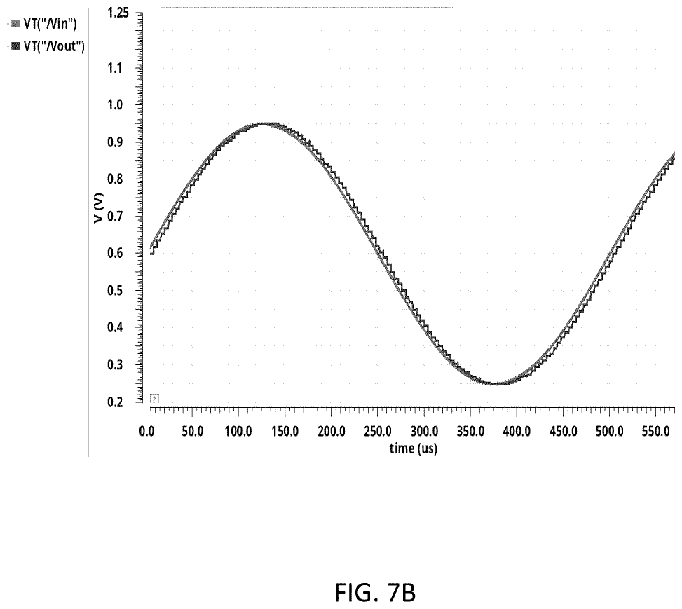

FIG. 7A shows a block diagram of a portion of the 8-bit SAR ADC of FIG. 2 where a portion of the ADC is coupled to an 8-bit DAC. Applying the designed 8-bit SAR ADC output to an 8-bit DAC, the signal input to the ADC may be reconstructed (e.g., for comparison with other signals) after converting it to a digital signal. FIG. 7B shows a graph of the input voltage of the ADC portion of FIG. 7A and output voltage of the DAC of FIG. 7A as a function of time. The graph shows the result of a simulation. The input voltage in the graph was a continuous waveform, representing the analog voltage signal being input to the ADC. The output voltage in the graph showed the voltage produced by the DAC as it converted the digital output of the ADC back to an analog signal. The output waveform generally followed the shape of the input voltage, and had a staircase pattern, which helped demonstrate how accurately the DAC reproduced the signal input to the ADC and also helped evaluate the performance of the ULP temperature sensing system described herein.

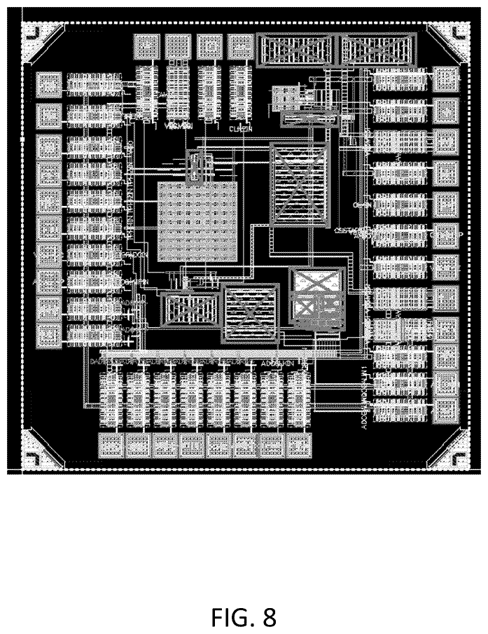

FIG. 8 shows a chip comprising the ultra-low power (ULP) temperature sensing system.

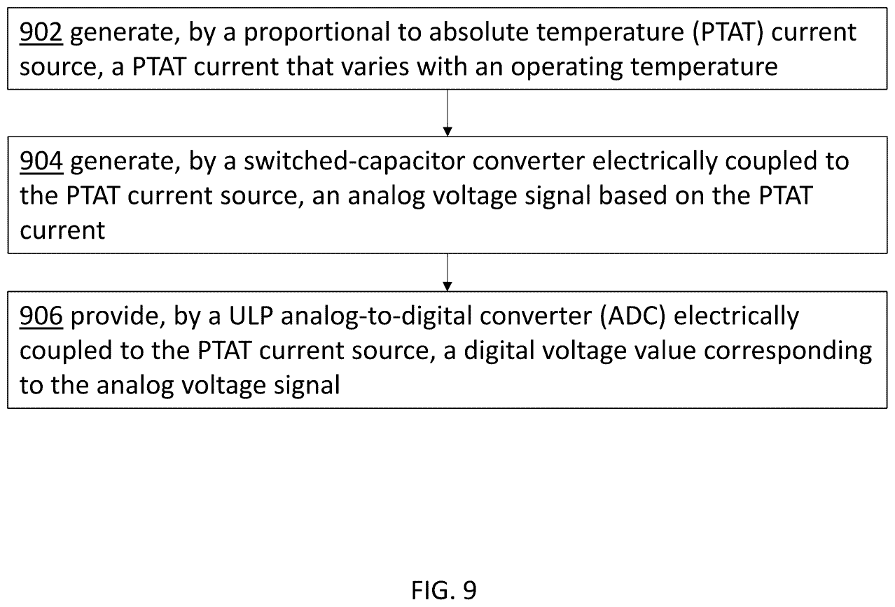

A method for temperature sensing is presented herein. FIG. 9 is a flow chart depicting a method for temperature sensing. At 902, a PTAT current that varies with an operating temperature may be generated by a PTAT current source. At 904, an analog voltage signal, based on the PTAT current, may be generated by a switched-capacitor converter electrically coupled to the PTAT current source. At 906, a digital value corresponding to the analog voltage signal may be provided by a ULP ADC electrically coupled to the PTAT current source.

### Conclusion

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the disclosed subject matter is described herein in terms of certain preferred embodiments, those skilled in the art will recognize that various modifications and improvements may be made to the disclosed subject matter without departing from the scope thereof. For example, various systems, components, and/or techniques may be shown as using an 8-bit binary design, where greater or fewer bit designs may instead be used. Moreover, although individual features of one embodiment of the disclosed subject matter may be discussed herein or shown in the drawings of the one embodiment and not in other embodiments, it should be apparent that individual features of one embodiment may be combined with one or more features of another embodiment or features from a plurality of embodiments.

In addition to the specific embodiments claimed below, the disclosed subject matter is also directed to other embodiments having any other possible combination of the dependent features claimed below and those disclosed above. As such, the particular features presented in the dependent claims and disclosed above can be combined with each other in other manners within the scope of the disclosed subject matter such that the disclosed subject matter should be recognized as also specifically directed to other embodiments having any other possible combinations. Thus, the foregoing description of specific embodiments of the disclosed subject matter has been presented for purposes of illustration and description. It is not intended to be exhaustive or to limit the disclosed subject matter to those embodiments disclosed.

It will be apparent to those skilled in the art that various modifications and variations can be made in the method and system of the disclosed subject matter without departing from the spirit or scope of the disclosed subject matter. Thus, it is intended that the disclosed subject matter include modifications and variations that are within the scope of the appended claims and their equivalents.

Having thus described several illustrative embodiments, it is to be appreciated that various alterations, modifications, and improvements will readily occur to those skilled in the art. Such alterations, modifications, and improvements are intended to form a part of this disclosure, and are intended to be within the spirit and scope of this disclosure. While some examples presented herein involve specific combinations of functions or structural elements, it should be understood that those functions and elements may be combined in other ways according to the present disclosure to accomplish the same or different objectives. In particular, acts, elements, and features discussed in connection with one embodiment are not intended to be excluded from similar or other roles in other embodiments. Additionally, elements and components described herein may be further divided into additional components or joined together to form fewer components for performing the same functions. Accordingly, the foregoing description and attached drawings are by way of example only, and are not intended to be limiting.

What is claimed is:

1. An ultra-low power (ULP) temperature sensing system, the system comprising:
a proportional to absolute temperature (PTAT) current source, wherein the PTAT current source is configured to generate a PTAT current that varies with an operating temperature;
a switched-capacitor converter electrically coupled to the PTAT current source, wherein the switched-capacitor converter is configured to generate an analog voltage signal based on the PTAT current; and
a ULP analog-to-digital converter (ADC) electrically coupled to the PTAT current source and the switched-capacitor converter, wherein the ULP ADC is configured to output a digital voltage value corresponding to the analog voltage signal.

2. The system of claim 1, wherein the analog voltage signal is proportional to the operating temperature.

3. The system of claim 1, wherein the PTAT current source is biased sub-threshold.

4. The system of claim 1, wherein the PTAT current source comprises a constant transconductance.

5. The system of claim 1, wherein the PTAT current source comprises at least one MOSFET transistor electrically coupled to a plurality of BJT transistors.

6. The system of claim 5, wherein the at least one metal-oxide-semiconductor field-effect transistor (MOSFET) transistor comprises an NMOS transistor, and wherein the plurality of bipolar junction transistors (BJTs) comprises a plurality of PNP transistors.

7. The system of claim 1, wherein the switched-capacitor converter comprises at least one switched-capacitor based resistance, wherein the analog voltage signal is generated by the PTAT current flowing through the switched-capacitor based resistance.

8. The system of claim 7, wherein the at least one switched-capacitor based resistance comprises a plurality of switched capacitors, wherein a switching frequency of the plurality of switched capacitors is a clock frequency of a crystal oscillator (XO).

9. The system of claim 1, wherein the ULP ADC comprises a Successive Approximation Register (SAR) ULP ADC.

10. The system of claim 1, wherein the ULP ADC comprises a comparator, sample and hold circuit, and a digital-to-analog converter (DAC), wherein an output of the sample and hold circuit and an output of the DAC are electrically coupled to inputs of the comparator, and wherein the sample and hold circuit is configured to receive the analog voltage signal as input.

11. The system of claim 10, wherein the ULP ADC further comprises Successive Approximation Register (SAR) logic coupled to an output of the comparator and to inputs of the DAC, and wherein the SAR logic is configured to output the digital voltage value.

12. A method for temperature sensing, the method comprising:
generating, by a proportional to absolute temperature (PTAT) current source, a PTAT current that varies with an operating temperature;
generating, by a switched-capacitor converter electrically coupled to the PTAT current source, an analog voltage signal based on the PTAT current; and
providing, by a ULP analog-to-digital converter (ADC) electrically coupled to the PTAT current source, a digital voltage value corresponding to the analog voltage signal.

13. The method of claim 12, wherein the analog voltage signal is proportional to the operating temperature.

14. The method of claim 12, wherein the PTAT current source is biased sub-threshold.

15. The method of claim 12, wherein the PTAT current source comprises a constant transconductance.

16. The method of claim 12, wherein the PTAT current source comprises at least one MOSFET transistor electrically coupled to a plurality of BJT transistors.

17. The method of claim 16, wherein the at least one metal-oxide-semiconductor field-effect transistor (MOSFET) transistor comprises an NMOS transistor, and wherein the plurality of bipolar junction transistors (BJTs) comprises a plurality of PNP transistors.

18. The method of claim 12, wherein the switched-capacitor converter comprises at least one switched-capacitor based resistance, and wherein the method further comprises:
generating, by the PTAT current flowing through the switched-capacitor based resistance, an analog voltage signal.

19. The method of claim 18, wherein the at least one switched-capacitor based resistance comprises a plurality of switched capacitors, and wherein a switching frequency of the plurality of switched capacitors is a clock frequency of a crystal oscillator (XO).

20. The method of claim 12, wherein the ULP ADC comprises a Successive Approximation Register (SAR) ULP ADC.

21. The method of claim 12, wherein the ULP ADC comprises a comparator, sample and hold circuit, and a digital-to-analog converter (DAC), wherein an output of the sample and hold circuit and an output of the DAC are electrically coupled to inputs of the comparator, and wherein the method further comprises:
receiving, by the sample and hold circuit, the analog voltage signal.

22. The method of claim 21, wherein the ULP ADC further comprises Successive Approximation Register (SAR) logic coupled to an output of the comparator and to inputs of the DAC, and wherein the method further comprises:
outputting, by the SAR logic, the digital voltage value.
